(19) United States
(12) Patent Application Publication
(10) Pub. No.: US 2018/0033925 A1
(43) Pub. Date: Feb. 1, 2018

(54) METHOD OF PRODUCING A LIGHT-EMITTING DEVICE, AND LIGHT-EMITTING DEVICE

(71) Applicant: OSRAM Opto Semiconductors GmbH, Regensburg (DE)

(72) Inventors: Markus Pindl, Tegernheim (DE); Siegfried Herrmann, Neukirchen (DE); Kathy Schmidtke, Mainburg (DE)

(21) Appl. No.: 15/550,968

(22) PCT Filed: Feb. 17, 2016
(86) PCT No.: PCT/EP2016/053363

§ 371 Date: Aug. 14, 2017

(30) Foreign Application Priority Data
Feb. 20, 2015 (DE) 10 2015 102 460.8

(51) Int. Cl. H01L 33/50; H01L 33/48; H01L 33/00; H01L 33/54; H01L 33/58

(52) U.S. Cl. CPC H01L 33/508; H01L 33/54; H01L 33/58; H01L 33/005; H01L 33/486; H01L 2933/0041; H01L 2933/005

(57) ABSTRACT

A method of producing a light-emitting device includes providing a carrier having a carrier top face and at least one light-emitting semiconductor chip arranged on the carrier top face, wherein the semiconductor chip has a radiation emission face and is arranged on the carrier top face such that the radiation emission face faces away from the carrier top face; arranging a converter element on the at least one semiconductor chip on its radiation emission face so that the converter element fully covers the radiation emission face of the semiconductor chip and extends laterally beyond the semiconductor chip; covering the converter element with an encapsulant, and compression molding and curing the encapsulant so that the encapsulant covers the converter element on a face facing away from the semiconductor chip, and the converter element and the encapsulant fit closely against the radiation emission face and at least against a side face of the semiconductor chip; and detaching the encapsulant, together with the converter element and the semiconductor chip, from the carrier.

### TECHNICAL FIELD

This disclosure relates to a method of producing a light-emitting device and a light-emitting device.

### BACKGROUND

In the production of devices that emit white light, converter elements are usually drawn as films over an emission face of the light-emitting semiconductor chip, where the drawing process may result in a change in shape of the converter element. Alternative production processes use spraying, for example, to apply converter materials onto the semiconductor chip.

There is thus a need to provide a method of producing a light-emitting device and a light-emitting device characterized by an improved arrangement of converter elements on the external surfaces of a semiconductor chip.

### SUMMARY

We provide a method of producing a light-emitting device including providing a carrier having a carrier top face and at least one light-emitting semiconductor chip arranged on the carrier top face, wherein the semiconductor chip has a radiation emission face and is arranged on the carrier top face such that the radiation emission face faces away from the carrier top face; arranging a converter element on the at least one semiconductor chip on its radiation emission face so that the converter element fully covers the radiation emission face of the semiconductor chip and extends laterally beyond the semiconductor chip; covering the converter element with an encapsulant, and compression molding and curing the encapsulant so that the encapsulant covers the converter element on a face facing away from the semiconductor chip, and the converter element and the encapsulant fit closely against the radiation emission face and at least against a side face of the semiconductor chip; and detaching the encapsulant, together with the converter element and the semiconductor chip, from the carrier.

We also provide a light-emitting device including at least one semiconductor chip; a converter element including converter material introduced into a silicone film, wherein the converter element encloses the semiconductor chip on a radiation emission face and on the side faces, at least in places; an encapsulant that covers the converter element on faces facing away from the semiconductor chip, and wherein the semiconductor chip includes electrical contacts arranged on a face of the semiconductor chip that is free of the converter element and free of the encapsulant.

We further provide a method of producing a light-emitting device including providing a carrier having a carrier top face and at least one light-emitting semiconductor chip arranged on the carrier top face, wherein the semiconductor chip has a radiation emission face and is arranged on the carrier top face such that the radiation emission face faces away from the carrier top face; arranging a converter element on the at least one semiconductor chip on its radiation emission face so that the converter element fully covers the radiation emission face of the semiconductor chip and extends laterally beyond the semiconductor chip, wherein the converter element is a planar film, and includes a film material and at least one converter material introduced in the film material and wherein the converter element is in direct contact with the radiation emission face; covering the converter element with an encapsulant, and compression molding and curing the encapsulant so that the encapsulant covers the converter element on a face facing away from the semiconductor chip, and the converter element and the encapsulant fit closely against the radiation emission face and at least against a side face of the semiconductor chip; and detaching the encapsulant, together with the converter element and the semiconductor chip, from the carrier.

### BRIEF DESCRIPTION OF THE DRAWINGS

FIG. 1 shows a schematic cross section through a light-emitting device during production prior to compression molding of the converter element to the semiconductor chip.

FIG. 2 shows a schematic cross section through a light-emitting device after singulation of the encapsulant.

FIG. 3 shows in a schematic cross section the detachment of a carrier from the composite comprising the semiconductor chip, the converter element and the encapsulant.

FIG. 4 shows an example of the light-emitting device in a schematic cross section.

### DETAILED DESCRIPTION

In our method of producing a light emitting diode, a carrier having a carrier top face is provided, with at least one light-emitting semiconductor chip being arranged on the carrier top face. The semiconductor chip has a radiation emission face and is arranged on the carrier top face such that the radiation emission face faces away from the carrier top face.

For example, the carrier can be formed from a substrate or comprise a substrate. The semiconductor chip can be designed such that the generated radiation is emitted from a face facing away from the carrier surface in a direction away from the carrier surface. In addition, it is possible to design the semiconductor chip as a volume emitter. For instance, the semiconductor chip comprises a sapphire substrate. As regards the semiconductor chip, in principle, there are no restrictions on the nature and construction of the semiconductor chip arranged on the carrier surface. Electrical contact with the semiconductor chip is advantageously made by its bottom face. In particular, the semiconductor chip can be what is known as a flip-chip.

In a further method step, a converter element is arranged on the at least one semiconductor chip on its radiation emission face so that the converter element fully covers the radiation emission face of the semiconductor chip and extends laterally beyond the semiconductor chip.

The converter element advantageously comprises a converter material which converts at least some of the radiation emitted by the semiconductor chip, which radiation has a first wavelength, into radiation of a second wavelength. In addition, it is also advantageously possible that the converter element comprises one or more additional converter materials that convert the first wavelength of the radiation emitted by the semiconductor chip into radiation of other wavelengths, wherein the other wavelengths differ from the first wavelength.

The converter element can be arranged on the semiconductor chip by hand or machine, for instance, in an automated manner. The converter element is arranged such that the radiation emission face of the semiconductor chip is in direct contact with the converter element.

In a further method step, the converter element is covered by an encapsulant, and the converter element and the encapsulant are fitted closely against the radiation emission face and at least against a side face of the semiconductor chip by compression molding and curing of the encapsulant, wherein the encapsulant covers the converter element on a face facing away from the semiconductor chip.

The encapsulant is advantageously applied to the converter element on a face facing away from the semiconductor chip, the converter element being pressed against the semiconductor chip under a pressure significantly higher than the ambient pressure, for instance, significantly higher than the air pressure. The encapsulant transfers the pressure action to the converter element, fitting the converter element closely against the semiconductor chip. The pressure action can advantageously be increased to improve the closeness of fit against the semiconductor chip so that the converter element preferably terminates flush with the surfaces of the semiconductor chip and/or is in direct contact therewith. It is particularly advantageous here that the converter element, under suitably high pressure action, can also make a good close fit against corner regions of the surface of the semiconductor chip. To improve the closeness of fit of the converter element against the semiconductor chip, a flexible converter element is advantageously used.

Pressure and temperature are advantageously transferred from the carrier and via the encapsulant by compression molding to produce the close fit and adhesion of the converter element to the semiconductor chip. Compared to vacuum techniques, in this process a significantly higher pressure can be transferred via the encapsulant, thereby achieving an excellent closeness of fit of the converter element.

By virtue of the compression molding of a converter element arranged on the radiation emission face of the semiconductor chip and above the carrier top face, it is advantageously possible to produce a device comprising a converter element, which converter element has a constant thickness over the radiation emission face and the side faces of the semiconductor chip and also covers corner regions of the semiconductor chip.

There is advantageously no lateral displacement or expansion of the converter element relative to the radiation emission face of the semiconductor chip during positioning of the converter element above the semiconductor chip and during close-fitting of the converter element against the semiconductor chip. Pressure is transferred from the encapsulant to the converter element advantageously in a direction perpendicular to the carrier top face. A flexible converter element extending laterally beyond the semiconductor chip is pressed by the encapsulant at the protruding regions onto the side faces of the semiconductor chip and at least partially covers these side faces.

Thickness variations or cracks in the converter element caused by expansion can thereby advantageously be avoided.

In a further method step, the encapsulant, together with the converter element and the semiconductor chip, is detached from the carrier.

The cured encapsulant advantageously joins the semiconductor chip and the converter element and forms a housing for the light-emitting device. Since after curing, the assembly comprising semiconductor chip, converter element and encapsulant no longer needs any carrier as a supporting element, the carrier is advantageously detached from the semiconductor chip. If during production of the light-emitting device the converter element and/or the encapsulant have come into contact with the carrier, these are also detached from the carrier. After detachment, the light-emitting device comprises a semiconductor chip having a freely-accessible bottom face, on which are advantageously located electrical contacts.

A plurality of semiconductor chips may be arranged on the carrier top face spaced laterally apart from one another and, after detachment from the carrier, the encapsulant, together with the semiconductor chips and the converter elements, is singulated into individual devices.

In the arrangement of the converter element on the radiation emission face of a semiconductor chip, a converter element is advantageously used that advantageously covers and extends laterally beyond all the semiconductor chips on the carrier top face. The converter element is advantageously formed in one piece above the semiconductor chips.

If the converter element covers all the semiconductor chips and is formed from one piece, the converter element is pressed against the semiconductor chips and against the carrier top face by the encapsulant.

Singulation into individual devices takes place once the converter element, together with the encapsulant and the semiconductor chip, has been detached from the carrier. In this process, the encapsulant can advantageously be severed between the semiconductor chips, with each device resulting therefrom comprising at least one semiconductor chip. The singulation is performed by sawing, for example, although other singulation techniques are also possible.

The plurality of semiconductor chips, together with the encapsulant and the converter elements, may be detached as a strip from the carrier at an acute angle prior to singulation.

After the encapsulant has been cured, the semiconductor chip, the converter element and the encapsulant advantageously embody a solid composite. This composite is advantageously flexible. These properties allow the composite to be detached from the carrier as a strip. The detachment is advantageously performed at an acute angle with respect to the carrier top face. An angle that is not too steep reduces bending of the encapsulant and reduces stresses and damage arising thereby in the encapsulant, i.e. in the device. Such a detachment process is advantageously performed solely mechanically, thereby avoiding the need for any further process steps that would damage the encapsulant, the converter element or the semiconductor chip.

The converter element may be in the form of a film having a planar extent, and comprises a film material and at least one converter material introduced in the film material. The film material may comprise in particular a thermal release film that can be easily detached from the carrier at a raised temperature.

The advantageously flexible film material advantageously has a constant thickness and can be positioned on the at least one semiconductor chip using a simple positioning process. In a plurality of semiconductor chips, the film material can advantageously extend over, and laterally beyond, at least one semiconductor chip.

It is advantageous in this case that the converter material is already introduced into the film material before the converter element is applied. The converter material can form a converter layer inside the film material or preferably be distributed homogeneously in the film material. In particular, the converter material can be distributed in the film material in the form of converter particles.

The converter layer may have thicknesses of 40 μm to 80 μm, preferably of 40 μm to 60 μm. The filler content of the converter material in the film material advantageously equals 40 wt % to 80 wt %, preferably 50 wt % to 70 wt %.

The following are advantageously suitable as the converter material in the form of filler particles: (Y, Lu, Gd, Tb)₃ (Al₁₋ₓGaₓ)₅O₁₂; (Ba, Sr, Ca) Si₂O₂N₂; (Ba, Sr, Ca)₂SiO₄; (Ba, Sr, Ca)₂Si₅N₈; (Sr, Ca)AlSiN₃Si₂N₂O; (Sr, Ca)AlSiN₃; Ca₈Mg(SiO₄)Cl₂.

A mean particle size of the filler particles advantageously equals on average 5 μm to 30 μm, preferably 10 μm to 30 μm and more preferably 15 μm to 30 μm.

The film material may comprise a material that with rising temperature initially softens at least partially, with the result that the converter element fits closely against the semiconductor chip and adheres thereto, and which material sets as the temperature rises further.

The film material advantageously has both softening and setting properties (bi-stage material), and on being heated starts to melt on, or to fuse, at and above a characteristic melting point temperature. In the process, compression molding subjects the film material to a constantly rising temperature, and the temperature advantageously continues to rise above the characteristic melting point temperature. Above a characteristic setting point temperature, which advantageously is higher than the characteristic melting point temperature, the film material sets and no longer has a softening property. By these two properties, the film material allows the converter element to be fitted more closely to the shape of the semiconductor chip by virtue of slight softening and, in addition, allows the converter element to be cured in its final shape at a higher temperature. The rate of temperature rise can be adjusted in this case according to film material to suit the softening and setting properties thereof and with regard to the closeness of fit against the semiconductor chip.

The film material may comprise silicone.

The silicone advantageously means that the converter element is flexible. In this case, the converter material can be introduced into the silicone and form there advantageously a converter layer or a plurality of converter layers, each comprising different converter materials. The silicone advantageously exhibits good softening and setting properties with increasing temperature, and can be easily removed from the carrier after curing. Silicone is advantageously highly resistant to yellowing under exposure to short-wavelength light, in particular blue light. In addition, the silicone suitably forms particularly thin converter elements advantageously as films. By virtue of the softening and setting properties of the silicone, in a melting process during production of the device, a plurality of films can advantageously be joined together and fitted closely against the semiconductor chip, something that advantageously can be performed in a single process step.

The encapsulant may comprise liquid silicone.

Liquid silicone is suitable as an encapsulant to transfer pressure to the converter element during compression molding and press the converter element against the semiconductor chip. Once production of the device is complete, the encapsulant containing the silicone advantageously forms a final layer in the emission direction. The silicone advantageously comprises a methyl-based or phenyl-based silicone. In addition, it is also possible to provide a silicone with a filler material. Aluminum oxide or titanium oxide having particle sizes of 0.2 μm to 5 μm, preferably 0.2 μm to 2 μm, are suitable as the filler material for instance. The particle size can equal approximately 0.5 μm, for example.

The silicone of the encapsulant may be cured with a rise in temperature.

When the temperature rises, the silicone advantageously sets above a characteristic setting point temperature. This advantageously achieves a composite comprising semiconductor chip, converter element and encapsulant, which composite, on completion of the productions steps, forms the device, for instance, as a chip package.

The compression molding and curing may take place in a combined laminating and molding process.

Pressing the converter element against the semiconductor chip and melting-on of the converter element with a rise in temperature and setting of the converter element after fitting closely against the semiconductor chip are advantageously performed in a single process step under a rising temperature. In the process step, a converter element is laminated on above the semiconductor chip and pressed into shape.

The semiconductor chip may comprise only electrical contacts facing the carrier top face.

The semiconductor chip is a flip-chip, for example, or a chip having a semiconductor layer sequence, in which chip, contact with the semiconductor layers can be made from the bottom face by vias into the respective semiconductor layers. Once the carrier has been detached, the devices have electrical contacts accessible from the bottom face, which is advantageously suitable for mounting and preferably simultaneously making contact on a connecting board, for example.

The converter element and the encapsulant may be fitted closely against the semiconductor chip such that the converter element is molded flush around the semiconductor chip on the radiation emission face and on all the side faces, and is in direct contact with the faces after being molded around.

Covering the semiconductor chip from all sides apart from the face facing the carrier is advantageously suitable for enclosing the semiconductor chip flush with the converter element and the encapsulant. In particular, for volume emitters that can laterally emit radiation, the converter element covers all emitting side faces and the radiation emission face. In addition, molding-around in this way provides the semiconductor chip with mechanical stability and thermal contact from all side faces and from the radiation emission face, which has an advantageous effect on conversion of the radiation and heat dissipation from the converter element and from the semiconductor chip.

The encapsulant may be formed such that, after curing, the surface of the encapsulant is shaped as an optical element.

The encapsulant can be formed as an optical element to influence the direction, beam shape or other properties of the emitted radiation. In this case, an emission face of the encapsulant can be concave or convex in shape, for example.

The encapsulant may be shaped as a lens.

To have a direct influence on the radiation, the lens shape can be formed directly above the radiation emission face of the semiconductor chip.

The light-emitting device may comprise at least one semiconductor chip, a converter element comprising converter material and a silicone film, introduced into which is the converter material, wherein the converter element encloses the semiconductor chip on a radiation emission face and on the side faces, at least in places, and an encapsulant, wherein the encapsulant covers the converter element on the faces facing away from the semiconductor chip. The semiconductor chip comprises electrical contacts arranged on a face of the semiconductor chip covered neither by the converter element nor by the encapsulant.

A film comprising silicone comprises at least one converter material, and forms a converter element attached to the semiconductor chip and the side faces thereof, at least in places, with the result that the converter element converts radiation emitted from the semiconductor chip at the radiation emission face and/or at the side faces. The encapsulant and the converter element fit closely against the contours of the semiconductor chip such that they match the shape of the contours, wherein the encapsulant is cured and advantageously acts as encapsulation of the semiconductor chip. The device can thus be in the form of a chip package. The semiconductor chip advantageously has contacts on its bottom face, which is not covered by a converter element and an encapsulant.

The description of the method provides further examples of the light-emitting device, and vice versa.

Further advantages and developments appear in the examples described below in connection with the figures.

In each of the figures, the same reference numbers are used to denote identical or equivalent elements. The elements shown and the relative sizes thereof shall not be considered to be to scale.

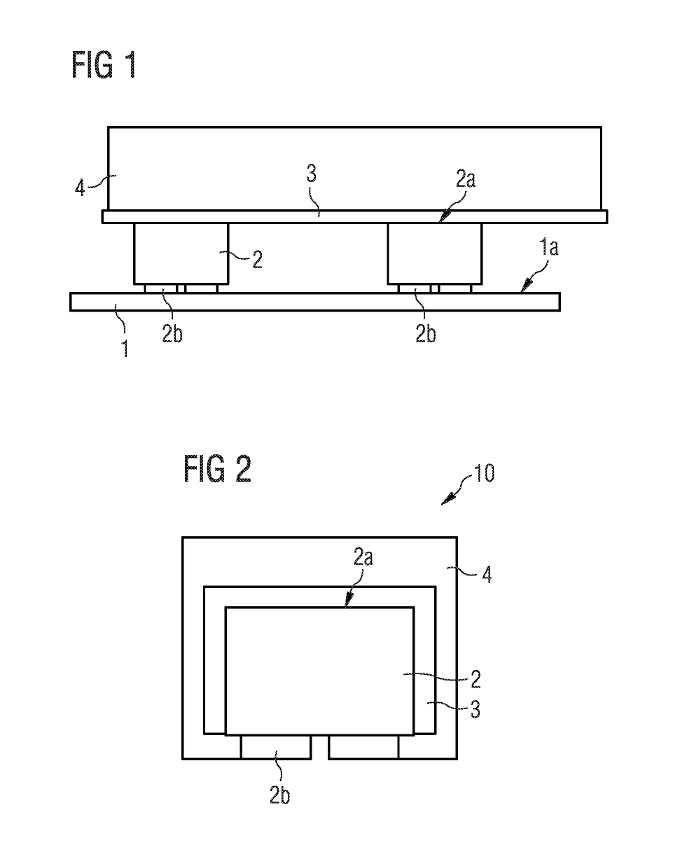

FIG. 1 shows in a schematic cross section a carrier 1 on which are arranged two semiconductor chips 2 spaced laterally apart from one another. The semiconductor chips 2 each comprise two electrical contacts 2b facing the carrier top face 1a. FIG. 1 also shows a converter element 3 that advantageously can be in the form of a film material, comprises at least one converter material and extends laterally beyond the semiconductor chips 2, entirely covering the semiconductor chips 2 on the radiation emission faces 2a thereof. The converter element 3 has a constant thickness between a face facing the semiconductor chips 2 and a face facing away from the semiconductor chips 2. The converter element 3 can advantageously be arranged above the semiconductor chips 2, which can be performed in a method step by hand or by machine, for instance, in an automated manner.

Advantageously, the converter element 3 is not subject to any lateral stretching or pulling forces during arrangement on the semiconductor chips 2, whereby any damage such as cracking, for instance, can be prevented or at least greatly reduced.

The semiconductor chips 2 can be, for example, volume emitters, for instance, comprising a sapphire substrate.

In a further method step, the converter element 3 is covered by an encapsulant 4, and the advantageously flexible converter element 3 is pressed against the radiation emission face 2a and against the side faces of the semiconductor chip 2 by compression molding and curing the encapsulant 4.

The encapsulant 4 is advantageously applied on the converter element 3 on a face facing away from the semiconductor chip 2, the converter element 3 being pressed against the semiconductor chip under a pressure significantly higher than the ambient pressure, for instance, significantly higher than the air pressure.

The encapsulant transfers the pressure action to the converter element 3 and fits the converter element closely against the semiconductor chip 2. The pressure action can advantageously be increased to improve the closeness of fit against the semiconductor chip 2 so that the converter element 3 preferably terminates flush with the surfaces of the semiconductor chip 2. Particularly advantageously, the converter element 3, under suitably high pressure action, can be fitted closely in a precision fit against corner regions of the surface of the semiconductor chip 2, as shown in FIG. 2.

FIG. 2 shows in a schematic cross section a light-emitting device 10 after the semiconductor chip 2, comprising the converter element 3, the encapsulant 4 and the electrical contacts 2b, has been detached from a carrier, as shown in FIG. 1, and the encapsulant 4 has been singulated, for instance, sawn.

After pressure has been applied by the encapsulant 4, the converter element 3 fits closely entirely against side faces and against the radiation emission face 2a of the semiconductor chip 2.

The converter element 3 as a film material, for example, has both softening and setting properties and, when the film material is heated, at and above a characteristic melting point temperature it starts to melt on. In the process, compression molding subjects the film material to a constantly rising temperature, and the temperature advantageously continues to rise above the characteristic melting point temperature. Above a characteristic setting point temperature advantageously higher than the characteristic melting point temperature, the film material sets and no longer has a softening property. By these two properties, the film material allows the converter element to be fitted more closely to the shape of the semiconductor chip by virtue of slight softening, and in addition allows the converter element to be cured in its final shape at a higher temperature. The rate of temperature rise can be adjusted in this case according to film material to suit the softening and setting properties thereof and with regard to the closeness of fit against the semiconductor chip.

Covering the converter element 3 with the encapsulant shown in FIG. 1, and the compression molding and subsequent curing to form the device composite shown in FIG. 2 are performed in a single process step.

The converter element advantageously has a constant thickness once the device has been produced.

The encapsulant 4 is advantageously singulated such that the encapsulant 4 also covers and laterally encloses the portions of the converter element 3 that cover the side faces of the semiconductor chip 2. The cured encapsulant 4 thereby advantageously acts as encapsulation of the semiconductor chip 2 and of the converter element 3.

The encapsulant 4 extends on the bottom face of the device 10 up to the electrical contacts 2b. For instance, the encapsulant 4 terminates in a planar and flush fit with the electrical contacts 2b at the faces thereof facing away from the semiconductor chip 2. The device has no encapsulant 4 between the electrical contacts 2b, and also the electrical contacts 2b themselves are not covered by the encapsulant 4. During mounting, contact with the semiconductor chip 2 can be made advantageously from the bottom face.

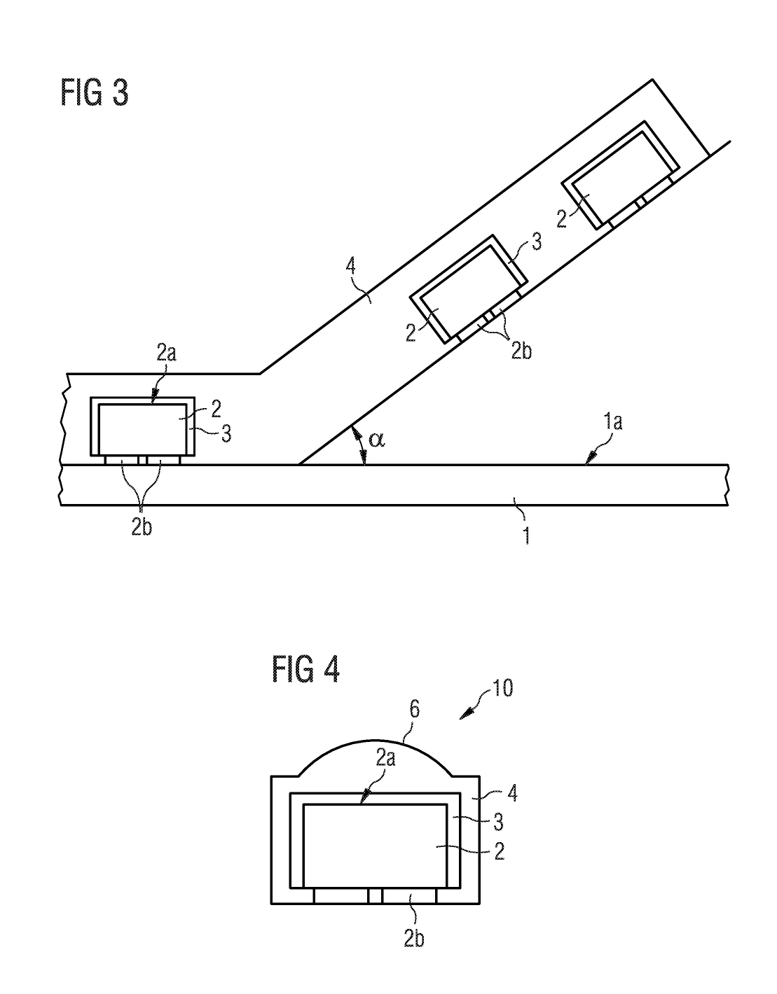

FIG. 3 shows in a schematic cross section the detachment from a carrier 1 of a flexible composite composed of a plurality of semiconductor chips 2 comprising converter elements 3 and an encapsulant 4. The composite is advantageously detached from the carrier 1 as a strip at an acute angle α before singulation.

The detachment is advantageously performed at an acute angle with respect to the carrier top face 1a. An angle that is not too steep reduces bending of the encapsulant and reduces stresses and damage arising thereby in the encapsulant, i.e. in the device. Such a detachment process is advantageously performed solely mechanically, thereby avoiding the need for any further process steps that would damage the encapsulant, the converter element or the semiconductor chip.

The flexibility of the encapsulant 4 and an angle α that is not too steep reduce or entirely prevent the occurrence of damage such as cracks in the encapsulant 4.

The strip comprising the semiconductor chips 2 is advantageously detached from the carrier 1 such that the electrical contacts 2b are exposed after the detachment. There is advantageously no encapsulant 4 between the electrical contacts 2b. For the detached strip, the encapsulant 4 can subsequently be singulated and individual devices produced.

FIG. 4 shows in a schematic cross section the light-emitting device 10 in finished form, with the encapsulant 4 having a lens shape 6 on an emission face above radiation emission face 2a of the semiconductor chip 2. The encapsulant 4 encapsulates the semiconductor chip 2 and the converter element 3 while also forming by its surface an optical element.

The description based on the examples has no limiting effect on this disclosure. Indeed the disclosure includes every novel feature and every combination of features, which in particular includes every combination of features in the appended claims, even if the feature or combination is not itself explicitly mentioned in the claims or examples.

This application claims priority of DE 10 2015 102 460.8, the subject matter of which is incorporated herein by reference.

1.-14. (canceled)

15. A method of producing a light-emitting device comprising:
providing a carrier having a carrier top face and at least one light-emitting semiconductor chip arranged on the carrier top face, wherein the semiconductor chip has a radiation emission face and is arranged on the carrier top face such that the radiation emission face faces away from the carrier top face;
arranging a converter element on the at least one semiconductor chip on its radiation emission face so that the converter element fully covers the radiation emission face of the semiconductor chip and extends laterally beyond the semiconductor chip;
covering the converter element with an encapsulant, and compression molding and curing the encapsulant so that the encapsulant covers the converter element on a face facing away from the semiconductor chip, and the converter element and the encapsulant fit closely against the radiation emission face and at least against a side face of the semiconductor chip; and
detaching the encapsulant, together with the converter element and the semiconductor chip, from the carrier.

16. The method according to claim 15, wherein a plurality of semiconductor chips are arranged on the carrier top face spaced laterally apart from one another and, after detachment from the carrier, the encapsulant, together with the semiconductor chips and the converter elements, is singulated into individual devices.

17. The method according to claim 15, wherein the plurality of semiconductor chips, together with the encapsulant and the converter elements, are detached as a strip from the carrier at an acute angle prior to singulation.

18. The method according to claim 15, wherein the converter element is a planar film, and comprises a film material and at least one converter material introduced in the film material.

19. The method according to claim 18, wherein the film material comprises a material that, with rising temperature, initially softens at least partially such that the converter element fits closely against the semiconductor chip and adheres thereto, and which material sets as the temperature rises further.

20. The method according to claim 19, wherein the film material comprises silicone.

21. The method according to claim 15, wherein the encapsulant comprises liquid silicone.

22. The method according to claim 21, wherein the silicone of the encapsulant is cured with a rise in temperature.

23. The method according to claim 15, wherein the compression molding and curing take place in a combined laminating and molding process.

24. The method according to claim 15, wherein the semiconductor chip comprises only electrical contacts that face the carrier top face.

25. The method according to claim 15, wherein the converter element and the encapsulant are fitted closely against the semiconductor chip such that the converter element is molded flush around the semiconductor chip on the radiation emission face and on all the side faces, and is in direct contact with said faces after being molded around.

26. The method according to claim 15, wherein the encapsulant is formed such that after curing, the surface of the encapsulant is shaped as an optical element.

27. The method according to claim 26, wherein the encapsulant is shaped as a lens.

28. A light-emitting device comprising:
at least one semiconductor chip;
a converter element comprising converter material introduced into a silicone film, wherein the converter element encloses the semiconductor chip on a radiation emission face and on the side faces, at least in places;
an encapsulant that covers the converter element on faces facing away from the semiconductor chip, and wherein the semiconductor chip comprises electrical contacts arranged on a face of the semiconductor chip that is free of the converter element and free of the encapsulant.

29. A method of producing a light-emitting device comprising:
providing a carrier having a carrier top face and at least one light-emitting semiconductor chip arranged on the carrier top face, wherein the semiconductor chip has a radiation emission face and is arranged on the carrier top face such that the radiation emission face faces away from the carrier top face;
arranging a converter element on the at least one semiconductor chip on its radiation emission face so that the converter element fully covers the radiation emission face of the semiconductor chip and extends laterally beyond the semiconductor chip, wherein the converter element is a planar film, and comprises a film material and at least one converter material introduced in the film material and wherein the converter element is in direct contact with the radiation emission face;
covering the converter element with an encapsulant, and compression molding and curing the encapsulant so that the encapsulant covers the converter element on a face facing away from the semiconductor chip, and the converter element and the encapsulant fit closely against the radiation emission face and at least against a side face of the semiconductor chip; and
detaching the encapsulant, together with the converter element and the semiconductor chip, from the carrier.
